(19) United States
(12) Patent Application Publication
(10) Pub. No.: US 2024/0105540 A1
(43) Pub. Date: Mar. 28, 2024

(54) DISPLAY DEVICE INCLUDING A DISPLAY SUBSTRATE AND A POLARIZATION LAYER

(71) Applicant: SAMSUNG DISPLAY CO., LTD., YONGIN-SI (KR)

(72) Inventor: Younhwan JUNG, Yongin-si (KR)

(21) Appl. No.: 18/476,211

(22) Filed: Sep. 27, 2023

(30) Foreign Application Priority Data
Sep. 28, 2022 (KR) 10-2022-0123556

(51) Int. Cl. H01L 23/31

(52) U.S. Cl. CPC H01L 23/3157; H01L 25/0657

(57) ABSTRACT

A display device includes a display substrate including a display area, a peripheral area adjacent to the display area, and a pad area extending from a side of the peripheral area in a first direction, a polarization layer disposed on a front surface of the display substrate, and including a first portion covering the display area and the peripheral area adjacent to the display area, and a second portion extending from the first portion to cover at least a portion of the pad area, an integrated circuit chip disposed on the front surface of the display substrate in the pad area, and a connection element including a first portion disposed on the front surface of the display substrate in the pad area.

### CROSS-REFERENCE TO RELATED APPLICATION

This application claims priority under 35 USC § 119 to Korean Patent Application No. 10-2022-0123556, filed on Sep. 28, 2022, in the Korean Intellectual Property Office (KIPO), the disclosure of which is hereby incorporated by reference in its entirety.

### TECHNICAL FIELD

Embodiments of the present inventive concept provide generally to a display device. More particularly, embodiments of the present inventive concept relate to a display device including a display substrate and a polarization layer.

### DISCUSSION OF RELATED ART

A display device may include a display substrate. The display substrate may include an upper substrate and a lower substrate bonded together. The combination of the upper substrate and the lower substrate may increase a strength of the display substrate. Such a display substrate, including the upper substrate and the lower substrate, may be resistant to impacts.

In single layer display substrates, such as a flexible display substrates, the display substrate may be vulnerable to damage due to an external force. The external force may result in cracks in the display substrate. The cracks may lead to defects in the display substrate. In this case, display performance may deteriorate.

### SUMMARY

Embodiments provide a display device with improved resistance to impact damage.

A display device according to embodiments of the present invention may include a display substrate including a display area, a peripheral area adjacent to the display area, and a pad area extending from a side of the peripheral area in a first direction, a polarization layer disposed on a front surface of the display substrate, and including a first portion covering the display area and the peripheral area adjacent to the display area, and a second portion extending from the first portion to cover at least a portion of the pad area, an integrated circuit chip disposed on the front surface of the display substrate in the pad area, and a connection element including a first portion disposed on the front surface of the display substrate in the pad area.

In an embodiment, the second portion of the polarization layer may include a first extension portion extending from the first portion of the polarization layer in the first direction, and covering at least a portion of the pad area adjacent to the peripheral area, and at least one second extension portion extending from the first extension portion in the first direction.

In an embodiment, the second extension portion may be spaced apart from the integrated circuit chip and the connection element in a plan view.

In an embodiment, the second extension portion may be positioned adjacent to a corner of the display substrate in the pad area.

In an embodiment, the second extension portion may further include a protrusion portion that may extend beyond the display substrate in a plan view.

In an embodiment, the protrusion portion may be adjacent to the corner of the display substrate in the pad area.

In an embodiment, the integrated circuit chip may be positioned between two second extension portions, including the at least one second extension portion, in a plan view.

In an embodiment, the first portion of the connection element may be positioned between two second extension portions, including the at least one second extension portion, in a plan view.

In an embodiment, the display device may further include a cover panel disposed on a back surface of the display substrate opposite to the front surface of the display substrate, and a driving chip disposed on the cover panel.

In an embodiment, the connection element may be spaced apart from the integrated circuit chip in the first direction and may further include a second portion extending from the first portion and curved in a direction toward the back surface of the display substrate, and the second portion of the connection element may be electrically connected to the driving chip.

In an embodiment, the second portion of the connection element may be attached to the cover panel.

A display device according to embodiments of the present invention may include a display substrate including a display area, a peripheral area adjacent to the display area, and a pad area extending from a side of the peripheral area in a first direction, a polarization layer disposed on a front surface of the display substrate, and including a first portion covering the display area and the peripheral area adjacent to the display area, and a second portion extending from the first portion to cover at least a portion of the pad area, an integrated circuit chip disposed on a back surface opposite to the front surface of the display substrate in the pad area, and a connection element including a first portion disposed on the back surface of the display substrate in the pad area.

In an embodiment, the polarization layer may have a rectangular shape in a plan view.

In an embodiment, the second portion of the polarization layer may have a protrusion portion that may extend beyond the display substrate in a plan view.

In an embodiment, the display device may further include a cover panel disposed on the back surface of the display substrate, and a driving chip disposed on the cover panel.

In an embodiment, the integrated circuit chip may be spaced apart from the cover panel in the first direction.

In an embodiment, the connection element may be spaced apart from the integrated circuit chip in the first direction, and may further include a second portion extending from the first portion and having a curved shape, wherein the second portion of the connection element may be electrically connected to the driving chip.

In an embodiment, the second portion of the connection element may be attached to the cover panel.

A display device according to embodiments of the present invention may include, a display substrate comprising a display area, a peripheral area adjacent to the display area, and a pad area extending from a side of the peripheral area in a first direction, an integrated circuit chip disposed on the display substrate in the pad area, a connection element disposed on the display substrate in the pad area, and a polarization layer disposed on the display substrate, and comprising a first portion covering at least a portion of the display area and at least a portion of the peripheral area adjacent to the display area, and a second portion extending from the first portion to cover at least a portion of the pad area adjacent, wherein at least a portion of the second portion of the polarization layer is adjacent to at least a portion of the integrated circuit chip and at least a portion of the connection element in a second direction perpendicular to the first direction.

In an embodiment, the second portion of the polarization layer may be positioned adjacent to a corner of the display substrate in the pad area.

The display device according to embodiments may include a polarization layer including a second portion covering a pad area of a display substrate. Accordingly, the second portion of the polarization layer may serve to prevent the display substrate in the pad area from being damaged by an external force.

### BRIEF DESCRIPTION OF THE DRAWINGS

Illustrative, non-limiting embodiments will be more clearly understood from the following detailed description in conjunction with the accompanying drawings.

FIG. 1 is a diagram illustrating a plan view of a display device according to an embodiment.

FIG. 2 is a diagram illustrating a side view of the display device of FIG. 1.

FIG. 3 to FIG. 9 are diagrams illustrating area A and a polarization layer included in the display device of FIG. 1.

FIG. 10 is a diagram illustrating a plan view of a display device according to an embodiment.

FIG. 11 is a diagram illustrating a side view of the display device of FIG. 10.

### DETAILED DESCRIPTION

Hereinafter, embodiments of the present disclosure will be explained in detail with reference to the accompanying drawings. The same reference numerals are used for the same components in the drawings, and redundant descriptions of the same components may be omitted.

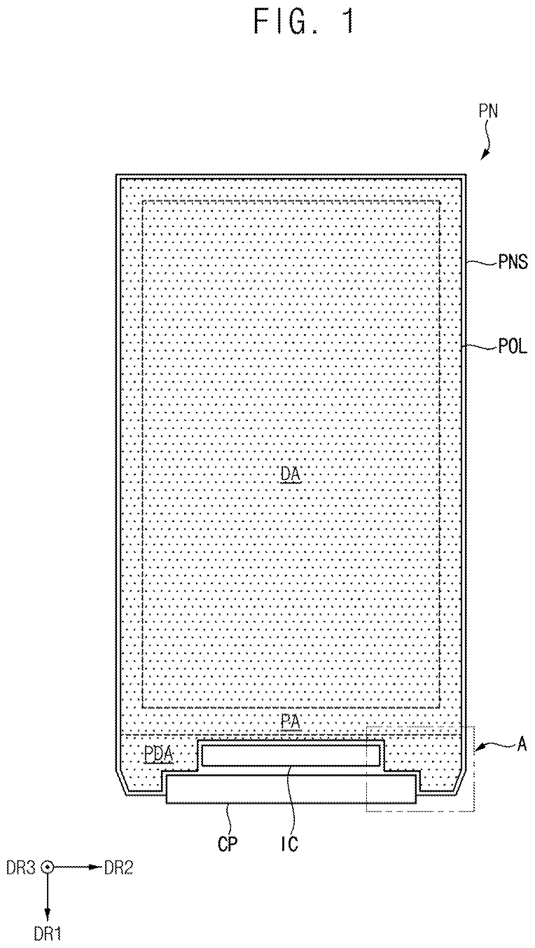

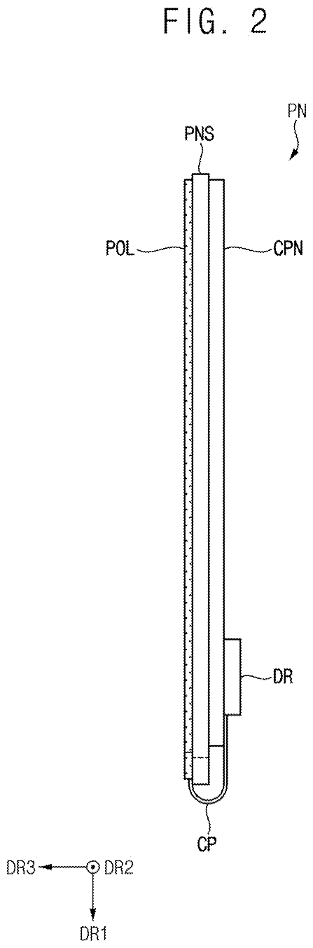

FIG. 1 is a diagram illustrating a plan view of a display device according to an embodiment. FIG. 2 is a diagram illustrating a side view of the display device of FIG. 1.

Referring to FIG. 1 and FIG. 2, a display device PN may include a display substrate PNS, a polarization layer POL, an integrated circuit chip IC, a connection element CP, a cover panel CPN, and a driving chip DR.

The display substrate PNS may include a front side and a back side. FIG. 1 is a plan view of the display device PN showing the front side of the display substrate PNS. The display substrate PNS may be a rigid type display substrate or a flexible type display substrate.

The display substrate PNS may be partitioned into a plurality of areas. For example, the display substrate PNS may include a display area DA, a peripheral area PA adjacent to the display area DA, and a pad area PDA extending from one side of the peripheral area PA in a first direction DR1. The peripheral area PA may surround the display area DA.

On the front surface of the display substrate PNS, a plurality of pixels may be disposed in the display area DA. For example, the plurality of pixels may be arranged along the first direction DR1 and a second direction DR2 crossing the first direction DR1. That is, the first direction DR1 and the second direction DR2 may be perpendicular to each other. The plurality of pixels PX disposed in the display area may emit light in a third direction DR3 crossing each of the first direction DR1 and the second direction DR2. A user of the display device PN viewing the display substrate PNS may see an image, where the image may be perceived by the user as a combination of the light emitted from the plurality of pixels.

A driving circuit (not shown) may be disposed in the peripheral area PA of the display substrate PNS. For example, the driving circuit may include, for example, a data driving circuit, a scan driving circuit, etc.

A plurality of pad electrodes may be disposed in the pad area PDA. The plurality of pad electrodes may be electrically connected to the plurality of pixels. The plurality of pad electrodes may be electrically connected to the driving circuit. The plurality of pad electrodes may be electrically connected to the integrated circuit chip IC. The plurality of pad electrodes may be electrically connected to the connection element CP.

The integrated circuit chip IC may be disposed on the front surface of the display panel PNS in the pad area PDA. The integrated circuit chip IC may generate a first driving signal, and at the same time, may be electrically connected to the plurality of pad electrodes. The first driving signal generated by the integrated circuit chip IC may be transmitted to the driving circuit and the plurality of pixels through the plurality of pad electrodes.

The connection element CP may include a plurality of portions. For example, the connection element CP may include a first portion and a second portion. The first portion of the connection element CP may be defined as a portion disposed on the front surface of the display substrate PNS in the pad area PDA. The first portion of the connection element CP may be electrically connected to the plurality of pad electrodes in the pad area PDA.

The second portion of the connection element CP may extend from the first portion of the connection element CP. The second portion of the connection element CP may be curved in a direction toward a back side of the display substrate PNS. That is, as shown in FIG. 2, at least a portion of the second portion of the connection element CP may be curved to have a certain curvature.

The cover panel CPN may be disposed on the back side of the display substrate PNS. The cover panel CPN may include a plurality of layers. For example, the cover panel CPN may include a cushion layer, a heat dissipation layer, and a protective film layer sequentially stacked on the back surface of the display substrate PNS.

The driving chip DR may be disposed on the back side of the display substrate PNS. For example, the diving chip DR may be disposed on the cover panel CPN. The driving chip DR may generate a second driving signal. The driving chip DR may be connected to the connection element CP. For example, a portion of the second portion of the connection element CP may be attached on the cover panel CPN and the portion of the second portion of the connection element CP may be electrically connected to the driving chip DR. Accordingly, the second driving signal generated by the driving chip DR may be transmitted to the driving circuit and the plurality of pixels through the connection element CP and the plurality of pad electrodes electrically connected to the connection element CP.

The polarization layer POL may be disposed on the front surface of the display substrate PNS. The polarization layer POL may extend the pad area PDA of the display substrate PNS. In some examples, the display substrate PNS may be a Low-Temperature PolySilicon (LTPS) substrate, a Thin Film Encapsulation (TFE) layer (not shown) may be disposed on the display substrate PNS, and the polarization layer POL may be disposed on the TFE layer, wherein the polarization layer POL extends to the pad area PDA of the display substrate PNS.

The polarization layer POL may include a first portion and one or more second portions. The first portion of the polarization layer POL may be a portion covering the display area DA and the peripheral area PA adjacent the display area DA.

The second portions of the polarization layer POL may be defined as portions extending from the first portion of the polarization layer POL in the first direction DR1. The second portions of the polarization layer POL may cover at least a portion of the pad area PDA. More specifically, the second portions of the polarization layer POL may be disposed to cover an area adjacent to corners of the display substrate PNS in the pad area PDA. Accordingly, the second portions of the polarization layer POL may serve to increase a strength of the display device PN and may prevent the display substrate PNS in the area adjacent to the corners from being damaged by an external force. That is, the second portions of the polarization layer POL may protect the display substrate PNS in the area adjacent to the corners.

In an embodiment, as shown in FIG. 1, the second portions of the polarization layer POL may be spaced apart from the integrated circuit chip IC and the connection element CP. In an embodiment, as shown in FIG. 1, the integrated circuit chip IC may be disposed between the second portions of the polarization layer POL, and the first portion of the connection element CP may be disposed between the second portions of the polarization layer POL. The second portions of the polarization layer POL may have symmetrical shapes, with the integrated circuit chip IC and the connection element CP interposed between the second portions. Hereinafter, for convenience of explanation, one of the second portions of the polarization layer POL disposed in the area A will be described as a reference. The second portions may be substantially similar, and the description of the second portion in area A may inform the structure of both second portions illustrated in FIG. 1.

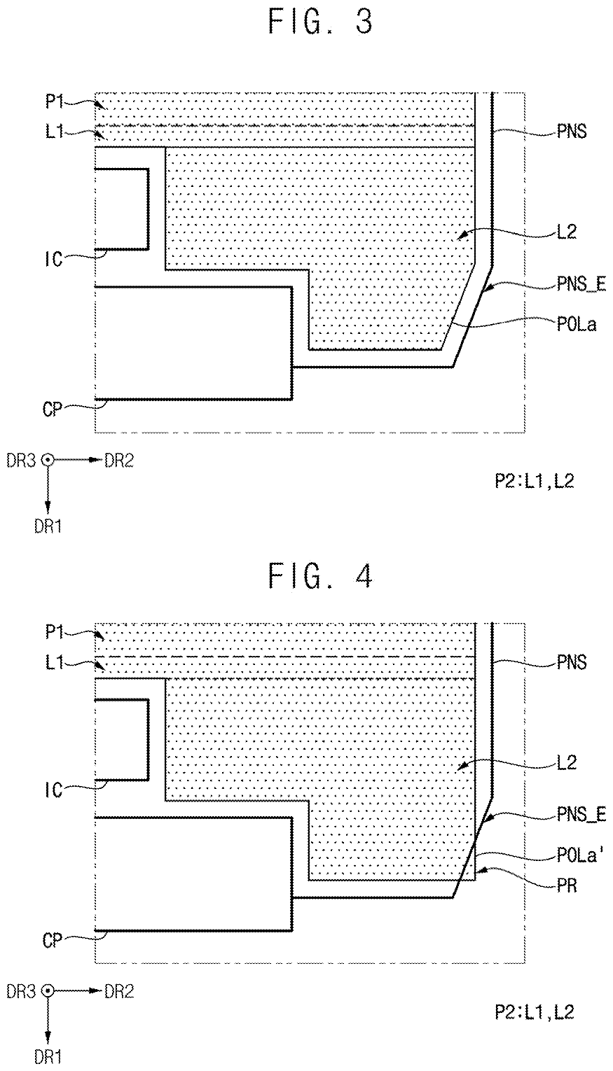

FIG. 3 to FIG. 9 are diagrams illustrating a polarization layer included in the display device of FIG. 1. FIG. 3 to FIG. 9 are plan views illustrating an enlarged area A of FIG. 1 for illustrating a polarization layer POL according to various embodiments of the present invention.

Referring to FIG. 3, a first polarization layer POLa, which is an embodiment of the polarization layer POL of FIG. 1, may include a first portion P1 and a second portion P2. The second portion P2 of the first polarization layer POLa may include a first extension portion L1 and a second extension portion L2.

The first portion P1 may be a portion of the first polarization layer POLa covering the display area DA and the peripheral area PA adjacent to the display area DA.

The first extension portion L1 may be a portion of the first polarization layer POLa extending from the first portion P1 in the first direction DR1. In this case, the first extension portion L1 may be defined as a portion of the first polarization layer POLa covering a portion of the pad area PDA adjacent to the peripheral area PA.

The second extension portion L2 may be a portion of the polarization layer POLa extending from the first extension portion L1 in the first direction DR1. The second extension portion L2 may cover an area adjacent to a corner PNS_E of the display substrate PNS in the pad area PDA. Accordingly, the second extension portion L2 may serve to prevent the display substrate PNS in the area adjacent to the corner PNS_E from being damaged by an external force. That is, the second extension portion L2 may protect the display substrate PNS in the area adjacent to the corner PNS_E.

The second extension portion L2 may be spaced apart from the integrated circuit chip IC and the first portion of the connection element CP. For example, as shown in FIG. 3, the second extension portion L2 may have a stepped edge formed along an edge of the integrated circuit chip IC adjacent to the second extension portion L2 and an edge of the connection element CP adjacent to the second extension portion L2. The second extension portion L2 may have other shapes, which may space the second extension portion L2 apart from the integrated circuit chip IC and the first portion of the connection element CP.

Referring to FIG. 4, a second polarization layer POLa′, which is an embodiment of the polarization layer POL of FIG. 1, may include a first portion P1 and a second portion P2. The second portion P2 of the second polarization layer POLa′ may include a first extension portion L1 and a second extension portion L2, and the second extension portion L2 may further include a protrusion portion PR.

As illustrated in FIG. 4, the first portion P1 and the first extension portion L1 of the second polarization layer POLa′ may be substantially the same as the first portion P1 and the first extension portion L1 of the first polarization layer POLa described with reference to FIG. 3, and the second extension portion L2 of the second polarization layer POLa′ may be substantially the same as the second extension portion L2 of the first polarization layer POLa described with reference to FIG. 3. In the example of the second polarization layer POLa′, the second extension portion L2 may further include the protrusion portion PR.

The second portion P2 of the second polarization layer POLa′ may include the protrusion portion PR that does not overlap the display substrate PNS in a plan view. In this case, the protrusion portion PR may be positioned adjacent to the corner PNS_E of the display substrate PNS in the pad area PDA. For example, the protrusion portion PR may be a corner of the second polarization layer POLa′ that extends beyond the corner PNS_E of the display substrate PNS in the pad area PDA.

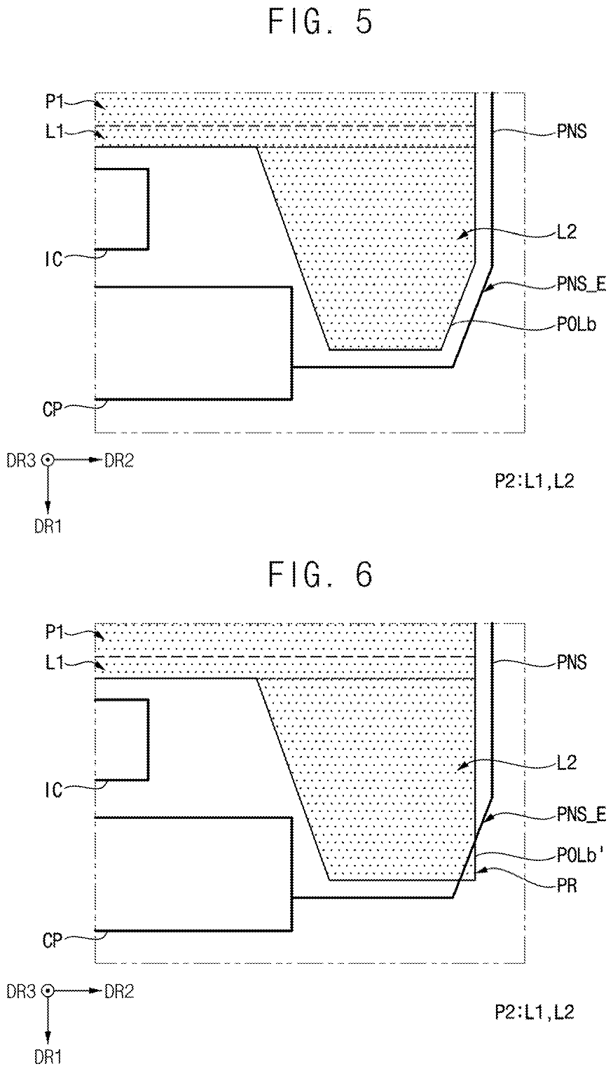

Referring to FIG. 5, a third polarization layer POLb, which is an embodiment of the polarization layer POL of FIG. 1, may include a first portion P1 and a second portion P2. The second portion P2 of the third polarization layer POLb may include a first extension portion L1 and a second extension portion L2.

The first portion P1 and the first extension portion L1 of the third polarization layer POLb may be substantially the same as the first portion P1 and the first extension portion L1 of the first polarization layer POLa described with reference to FIG. 3.

The second extension portion L2 may be a portion of the third polarization layer POLb extending from the first extension portion L1 in the first direction DR1. The second extension portion L2 may cover an area adjacent to the corner PNS_E of the display substrate PNS in the pad area PDA. Accordingly, the second extension portion L2 may serve to prevent the display substrate PNS in the area adjacent to the corner PNS_E from being damaged by an external force. That is, the second extension portion L2 may protect the display substrate PNS in the area adjacent to the corner PNS_E.

The second extension portion L2 may be spaced apart from the integrated circuit chip IC and the first portion of the connection element CP. For example, as shown in FIG. 5, an edge of the second extension portion L2 adjacent to the integrated circuit chip IC and the first portion of the connection element CP may extend along a direction between the first direction DR1 and the second direction DR2. The edge of the second extension portion L2 adjacent to the integrated circuit chip IC and the first portion of the connection element CP may extend from the first extension portion L1 at an angle, such that the edge may overlap a portion of the first portion of the connection element CP in the second direction DR2. The second extension portion L2 may have other shapes, which may space the second extension portion L2 apart from the integrated circuit chip IC and the first portion of the connection element CP.

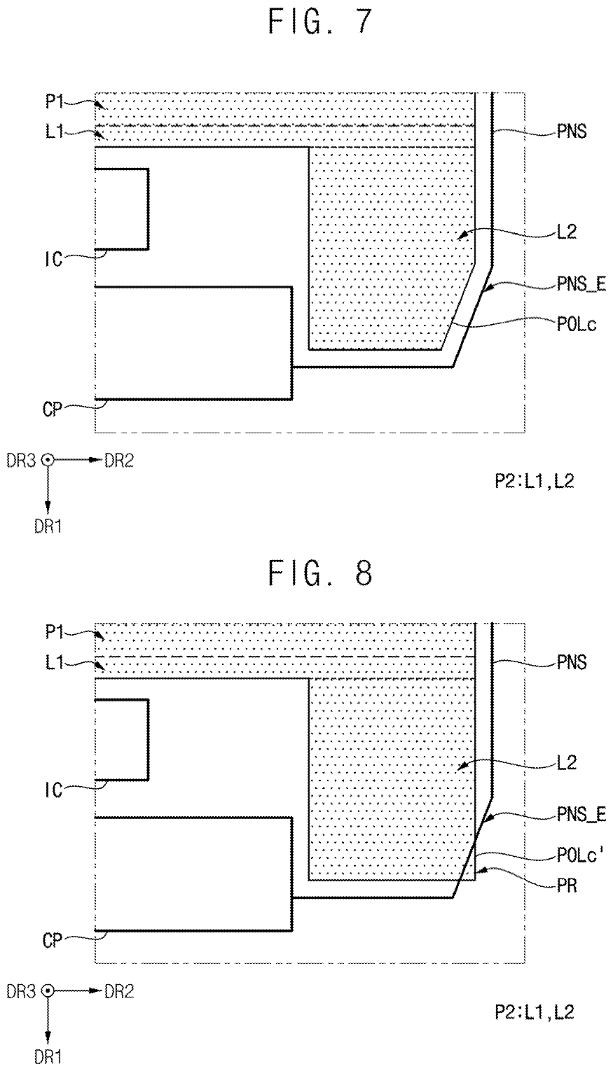

Referring to FIG. 6, a fourth polarization layer POLb′, which is an embodiment of the polarization layer POL of FIG. 1, may include a first portion P1 and a second portion P2. The second portion P2 of the fourth polarization layer POLb′ may include a first extension portion L1 and the second extension portion L2, and the second extension portion L2 may further include a protrusion portion PR.

In this case, the first portion P1 and the first extension portion L1 of the fourth polarization layer POLb′ may be substantially the same as the first portion P1 and the first extension portion L1 of the third polarization layer POLb described with reference to FIG. 5, and the second portion P2 of the fourth polarization layer POLb′ may be substantially the same as the second portion P2 of the third polarization layer POLb described with reference to FIG. 5. In the example of the fourth polarization layer POLb′, the second extension portion L2 may further include the protrusion portion PR.

The second portion P2 of the fourth polarization layer POLb′ may include the protrusion portion PR that does not overlap the display substrate PNS in a plan view. In this case, the protrusion portion PR may be positioned adjacent to the corner PNS_E of the display substrate PNS in the pad area PDA. For example, the protrusion portion PR may be a corner of the fourth polarization layer POLb′ that extends beyond the corner PNS_E of the display substrate PNS in the pad area PDA.

Referring to FIG. 7, a fifth polarization layer POLc, which is an embodiment of the polarization layer POL of FIG. 1, may include a first portion P1 and a second portion P2. The second portion P2 of the polarization layer POLc may include a first extension portion L1 and a second extension portion L2.

The first portion P1 and the first extension portion L1 of the polarization layer POLc may be substantially the same as the first portion P1 and the first extension portion L1 of the first polarization layer POLa described with reference to FIG. 3.

The second extension portion L2 may be a portion of the fifth polarization layer POLc extending from the first extension portion L1 in the first direction DR1. The second extension portion L2 may cover an area adjacent to the corner PNS_E of the display substrate PNS in the pad area PDA. Accordingly, the second extension portion L2 may serve to prevent the display substrate PNS in the area adjacent to the corner PNS_E from being damaged by an external force. That is, the second extension portion L2 may protect the display substrate PNS in the area adjacent to the corner PNS_E.

The second extension portion L2 may be spaced apart from the integrated circuit chip IC and the first portion of the connection element CP. For example, as shown in FIG. 7, an edge of the second extension portion CP adjacent to the integrated circuit chip IC and the first portion of the connection element CP may extend along the first direction DR1. The edge of the second extension portion L2 adjacent to the integrated circuit chip IC and the first portion of the connection element CP may extend from the first extension portion L1 at substantially a right angle. The second extension portion L2 may have other shapes, which may space the second extension portion L2 apart from the integrated circuit chip IC and the first portion of the connection element CP.

Referring to FIG. 8, a sixth polarization layer POLc′, which is an embodiment of the polarization layer POL of FIG. 1, may include a first portion P1 and the second portion P2. The second portion P2 of the sixth polarization layer POLc′ may include a first extension portion L1 and a second extension portion L2, and the second extension portion L2 may further include a protrusion portion PR.

In this case, the first portion P1 and the first extension portion L1 of the sixth polarization layer POLc′ may be substantially the same as the first portion P1 and the first extension portion L1 of the fifth polarization layer POLc described with reference to FIG. 7, and the second portion P2 of the sixth polarization layer POLc′ may be substantially the same as the second portion P2 of the fifth polarization layer POLc described with reference to FIG. 7. In the example of the sixth polarization layer POLc′, the second portion P2 may further include the protrusion portion PR.

The second portion P2 of the sixth polarization layer POLc′ may include the protrusion portion PR that does not overlap the display substrate PNS in a plan view. In this case, the protrusion portion PR may be positioned adjacent to the corner PNS_E of the display substrate PNS in the pad area PDA. For example, the protrusion portion PR may be a corner of the sixth polarization layer POLc′ that extends beyond the corner PNS_E of the display substrate PNS in the pad area PDA.

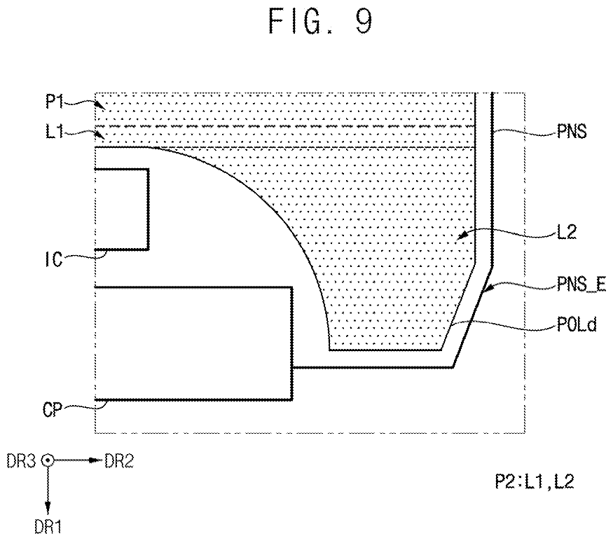

Referring to FIG. 9, a seventh polarization layer POLd, which is an embodiment of the polarization layer POL of FIG. 1, may include a first portion P1 and a second portion P2. The second portion P2 of the seventh polarization layer POLd may include a first extension portion L1 and the second extension portion P2.

The first portion P1 and the first extension portion L1 of the seventh polarization layer POLd may be substantially the same as the first portion P1 and the first extension portion L1 of the first polarization layer POLa described with reference to FIG. 3.

The second extension portion L2 may be a portion of the seventh polarization layer POLd extending from the first extension portion L1 in the first direction DR1. The second extension portion L2 may cover an area adjacent to the corner PNS_E of the display substrate PNS in the pad area PDA. Accordingly, the second extension portion L2 may serve to prevent the display substrate PNS in the area adjacent to the corner PNS_E from being damaged by an external force. That is, the second extension portion L2 may protect the display substrate PNS in the area adjacent to the corner PNS_E.

The second extension portion L2 may be spaced apart from the integrated circuit chip IC and the first portion of the connection element CP. For example, as shown in FIG. 9, an edge of the second extension portion L2 adjacent to the integrated circuit chip IC and the first portion of the connection element CP may have a round shape in which a width of the edge gradually decreases toward the first direction DR1. More generally, the edge of the second extension portion L2 adjacent to the integrated circuit chip IC and the first portion of the connection element CP may have a curved shape toward the first direction DR1. The second extension portion L2 may have other shapes, which may space the second extension portion L2 apart from the integrated circuit chip IC and the first portion of the connection element CP. For example, the curved shape may be formed of a plurality of linear sections.

In an embodiment, shown in FIG. 9, the second extension portion L2 of the seventh polarization layer POLd may further include a protrusion portion. The protrusion portion (not shown in FIG. 9) may be a portion of the seventh polarization layer POLd that does not overlap the display substrate PNS, and may be positioned adjacent to the corner PNS_E of the display substrate PNS in the pad area PDA. For example, the protrusion portion may be a corner of the seventh polarization layer POLd that extends beyond the corner PNS_E of the display substrate PNS in the pad area PDA. That is, the protrusion portion may be substantially the same as the protrusion portion PR illustrated in FIG. 4, for example.

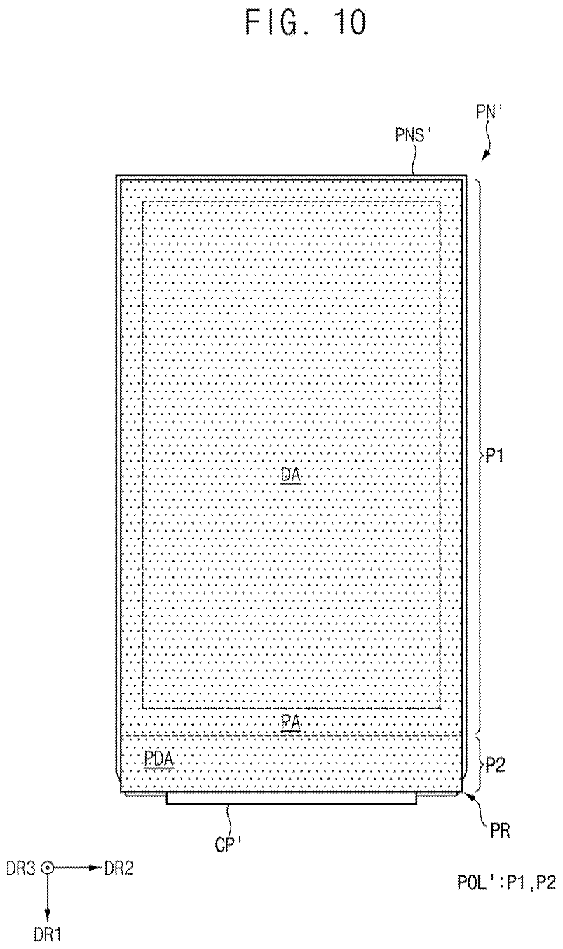

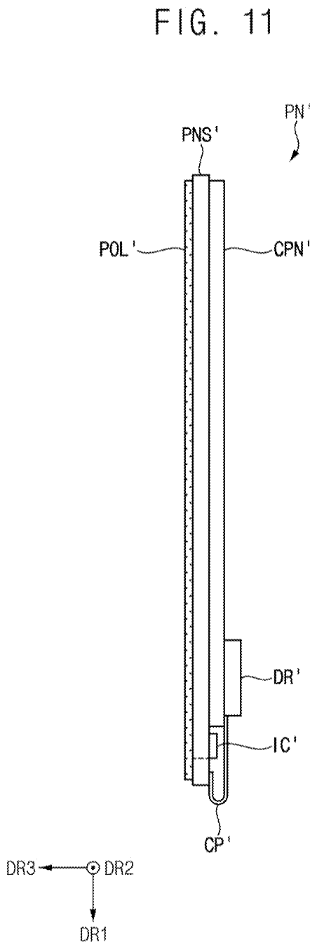

FIG. 10 and FIG. 11 are diagrams illustrating a display device according to another embodiment.

Referring to FIG. 10 and FIG. 11, a second display device PN′ may include a second display substrate PNS′, an eighth polarization layer POL′, a second integrated circuit chip IC′, a second connection element CP′, a second cover panel CPN′, and a second driving chip DR′.

The second display substrate PNS′ may be partitioned into a plurality of areas. For example, the second display substrate PNS′ may include a display area DA, a peripheral area PA surrounding the display area DA, and a pad area PDA extending from one side of the peripheral area PA in a first direction DR1.

On a back side of the second display substrate PNS′, a plurality of pixels may be generally disposed in the display area DA. For example, the plurality of pixels may be arranged along the first direction DR1 and the second direction DR2. The second display substrate PNS′ may be a back emission type display substrate.

Each of the pixels disposed in the display area DA may emit light. In this case, the pixels may be disposed on the back side of the second display substrate PNS′. Light emitted from the pixels may travel in the third direction DR3 crossing each of the first direction DR1 and the second direction DR2. Accordingly, the user of the second display device PN′ viewing the second display substrate PNS′ may see an image, where the image may be perceived by the user as a combination of the light emitted from the plurality of pixels.

A driving circuit (not shown) may be disposed in the peripheral area PA of the second display substrate PNS′. For example, the driving circuit may include a data driving circuit, a scan driving circuit, etc.

A plurality of pad electrodes may be disposed in the pad area PDA. The plurality of pad electrodes may be electrically connected to the plurality of pixels. The plurality of pad electrodes may be electrically connected to the driving circuit. The plurality of pad electrodes may be electrically connected to the second integrated circuit chip IC′. The plurality of pad electrodes may be electrically connected to the second connection element CP′.

The second integrated circuit chip IC′ may be disposed on the back surface of the display panel PNS′ in the pad area PDA. The integrated circuit chip IC′ may generate a first driving signal, and at the same time, may be electrically connected to the plurality of pad electrodes. The first driving signal generated by the integrated circuit chip IC′ may be transmitted to the driving circuit and the plurality of pixels through the plurality of pad electrodes.

The second connection element CP′ may include a plurality of portions. For example, the second connection element CP′ may include a first portion and a second portion. The first portion of the second connection element CP′ may be disposed on the back surface of the second display substrate PNS′ in the pad area PDA. The first portion of the second connection element CP′ may be electrically connected to the plurality of pad electrodes.

The second portion of the second connection element CP′ may extend from the first portion of the second connection element CP′ to have a curved shape. In other words, as shown in FIG. 11, at least a portion of the second portion of the second connection element CP′ may be curved to have a certain curvature.

The second cover panel CPN′ may be disposed on the back side of the second display substrate PNS′. The second cover panel CPN′ may include a plurality of layers. For example, the second cover panel CPN′ may include a cushion layer, a heat dissipation layer, and a protective film layer sequentially stacked on the back surface of the display substrate PNS.

The second driving chip DR′ may be disposed on the back side of the second display substrate PNS′. For example, the second diving chip DR′ may be disposed on the second cover panel CPN′. The second driving chip DR′ may generate a second driving signal. The second driving chip DR′ may be connected to the second connection element CP′. For example, a portion of the second portion of the second connection element CP′ may be attached on the second cover panel CPN′ and the portion of the second portion of the second connection element CP′ may be electrically connected to the second driving chip DR′. Accordingly, the second driving signal generated by the second driving chip DR′ may be transmitted to the driving circuit and the plurality of pixels through the second connection element CP′ and the plurality of pad electrodes electrically connected to the second connection element CP′.

The eighth polarization layer POL′ may be disposed on a front surface opposite to the back surface of the second display substrate PNS′. The eighth polarization layer POL′ may include a first portion P1 and a second portion P2.

The first portion P1 of the eighth polarization layer POL′ may be a portion covering the display area DA and the peripheral area PA adjacent to the display area DA.

The second portion P2 of the eighth polarization layer POL′ may be a portion extending from the first portion P1 in the first direction DR1. The second portion P2 may cover at least a portion of the pad area PDA. More specifically, the second portion P2 may cover an area adjacent to corners of the display substrate PNS′ in the pad area PDA. Accordingly, the second portion P2 of the eighth polarization layer POL′ may serve to prevent the second display substrate PNS′ in the area adjacent to the corner PNS_E from being damaged by an external force. That is, the second portion P2 of the eighth polarization layer POL′ may protect the display substrate PNS′ in the area adjacent to the corner PNS_E.

In an embodiment, the eighth polarization layer POL′ may have various shapes in a plan view. For example, the eighth polarization layer POL′ may have a shape described with reference to any of FIG. 3 to FIG. 9. The eighth polarization layer POL′ may have another shape. For another example, the eighth polarization layer POL′ may have a rectangular shape as shown in FIG. 10.

In an embodiment, the second portion P2 of the eighth polarization layer POL′ may include a protrusion portion PR that does not overlap the second display substrate PNS′ in a plan view. For example, the protrusion portion PR may be a corner of the eighth polarization layer POL′ that extends beyond an edge of the second display substrate PNS′.

The foregoing is illustrative of embodiments and is not to be construed as limiting thereof. Although methods and the apparatuses according to various embodiments of present inventive concept have been described, those skilled in the art will readily appreciate that many modifications are possible in illustrated embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a display substrate comprising a display area, a peripheral area adjacent to the display area, and a pad area extending from a side of the peripheral area in a first direction;
a polarization layer disposed on a front surface of the display substrate, and comprising a first portion covering the display area and the peripheral area adjacent to the display area, and a second portion extending from the first portion to cover at least a portion of the pad area;
an integrated circuit chip disposed on the front surface of the display substrate in the pad area; and
a connection element comprising a first portion disposed on the front surface of the display substrate in the pad area.

2. The display device of claim 1, wherein the second portion of the polarization layer comprises:
a first extension portion extending from the first portion of the polarization layer in the first direction, and covering at least a portion of the pad area adjacent to the peripheral area; and
at least one second extension portion extending from the first extension portion in the first direction.

3. The display device of claim 2 wherein the second extension portion is spaced apart from the integrated circuit chip and the connection element in a plan view.

4. The display device of claim 2, wherein the second extension portion is positioned adjacent to a corner of the display substrate in the pad area.

5. The display device of claim 4, wherein the second extension portion further includes a protrusion portion that extends beyond the display substrate in a plan view.

6. The display device of claim 5, wherein the protrusion portion is adjacent to the corner of the display substrate in the pad area.

7. The display device of claim 2, wherein the integrated circuit chip is positioned between two second extension portions, including the at least one second extension portion, in a plan view.

8. The display device of claim 2, wherein the first portion of the connection element is positioned between two second extension portions, including the at least one second extension portion, in a plan view.

9. The display device of claim 1, further comprising:
a cover panel disposed on a back surface of the display substrate opposite to the front surface of the display substrate; and
a driving chip disposed on the cover panel.

10. The display device of claim 9, wherein the connection element is spaced apart from the integrated circuit chip in the first direction and comprises a second portion extending from the first portion and curved in a direction toward the back surface of the display substrate and the second portion of the connection element is electrically connected to the driving chip.

11. The display device of claim 9, wherein the second portion of the connection element is attached to the cover panel.

12. A display device comprising:
a display substrate comprising a display area, a peripheral area adjacent to the display area, and a pad area extending from a side of the peripheral area in a first direction;
a polarization layer disposed on a front surface of the display substrate, and comprising a first portion covering the display area and the peripheral area adjacent to the display area, and a second portion extending from the first portion to cover at least a portion of the pad area;
an integrated circuit chip disposed on a back surface opposite to the front surface of the display substrate in the pad area; and
a connection element comprising a first portion disposed on the back surface of the display substrate in the pad area.

13. The display device of claim 12, wherein the polarization layer has a rectangular shape in a plan view.

14. The display device of claim 12, wherein the second portion of the polarization layer has a protrusion portion that extends beyond the display substrate in a plan view.

15. The display device of claim 12, further comprising:
a cover panel disposed on the back surface of the display substrate; and
a driving chip disposed on the cover panel.

16. The display device of claim 15, wherein the integrated circuit chip is spaced apart from the cover panel in the first direction.

17. The display device of claim 15, wherein the connection element is spaced apart from the integrated circuit chip in the first direction, and further comprises a second portion extending from the first portion and having a curved shape, wherein the second portion of the connection element is electrically connected to the driving chip.

18. The display device of claim 15, wherein the second portion of the connection element is attached to the cover panel.

19. A display device comprising:
a display substrate comprising a display area, a peripheral area adjacent to the display area, and a pad area extending from a side of the peripheral area in a first direction;
an integrated circuit chip disposed on the display substrate in the pad area;
a connection element disposed on the display substrate in the pad area; and
a polarization layer disposed on the display substrate, and comprising a first portion covering at least a portion of the display area and at least a portion of the peripheral area adjacent to the display area, and a second portion extending from the first portion to cover at least a portion of the pad area adjacent,
wherein at least a portion of the second portion of the polarization layer is adjacent to at least a portion of the integrated circuit chip and at least a portion of the connection element in a second direction perpendicular to the first direction.

20. The display device of claim 19, wherein the second portion of the polarization layer is positioned adjacent to a corner of the display substrate in the pad area.
